(19) United States
(12) Patent Application Publication
(10) Pub. No.: US 2026/0098904 A1
(43) Pub. Date: Apr. 9, 2026

(54) DIAGNOSIS SYSTEM

(71) Applicant: TOYOTA JIDOSHA KABUSHIKI KAISHA, Toyota-shi (JP)

(72) Inventors: Takayuki IRIE, Nisshin-shi (JP); Koichiro ISOBE, Okazaki-shi (JP); Tetsuo HARA, Toyota-shi (JP)

(73) Assignee: TOYOTA JIDOSHA KABUSHIKI KAISHA, Toyota-shi (JP)

(21) Appl. No.: 19/259,315

(22) Filed: Jul. 3, 2025

(30) Foreign Application Priority Data
Oct. 9, 2024 (JP) 2024-177110

(51) Int. Cl. G01R 31/367; B60L 58/12; H01M 10/42

(52) U.S. Cl. CPC G01R 31/367; B60L 58/12; H01M 10/4285; B60L 2240/545; H01M 2220/20

(57) ABSTRACT

A diagnosis system includes a storage device, an internal pressure transition estimation section, an amount-of-damage calculation section, and a durable-period prediction section. The storage device stores second history information. The internal pressure transition estimation section estimates the transition of the internal pressure of a battery. The amount-of-damage calculation section calculates the amount of damage to a housing of the battery by the internal pressure in accordance with a result of the estimation by the internal pressure transition estimation section after the end of use of the battery in the vehicle. The durable-period prediction section predicts the length of the durable period of the battery at the time of reuse in accordance with usage condition information and the amount of damage. The usage condition information indicates a usage condition of the battery imposed when the battery is reused after the end of use.

### CROSS-REFERENCE TO RELATED APPLICATION

This application claims priority to Japanese Patent Application No. 2024-177110 filed on Oct. 9, 2024. The disclosure of the above-identified application, including the specification, drawings, and claims, is incorporated by reference herein in its entirety.

### BACKGROUND

### 1. Technical Field

The present disclosure relates to a diagnosis system.

### 2. Description of Related Art

Japanese Unexamined Patent Application Publication No. 2020-061335 (JP 2020-061335 A) discloses a vehicle including a battery, a storage device, an airbag, and a control device. The storage device stores an actuation history of the airbag. The control device obtains information regarding vibration or impact of the vehicle based on the history. The control device evaluates (diagnoses) the reusability of the battery based on the obtained information.

### SUMMARY

A housing of the battery is easily damaged by the increasing internal pressure of the housing caused by gas generated in the battery. JP 2020-061335 A has studied nothing about such damage to the housing caused by the increasing internal pressure. As a result, the battery may be wrongly diagnosed as being reusable even when the battery is not actually reusable.

The present disclosure has been devised to solve the problem as described above. An object of the present disclosure is to provide a diagnosis system capable of appropriately diagnosing the reusability of a battery.

A diagnosis system according to the present disclosure is used to diagnose the reusability of a battery. The diagnosis system includes a storage unit, an estimation section, a calculation section, and a prediction section. The storage unit is configured to store history information indicating histories of the voltage, the electric current, and the temperature of the battery in a period in which the battery is installed in a vehicle. The estimation section is configured to estimate the transition of the internal pressure of the battery in accordance with the history information. The internal pressure changes depending on the elapsed time from the start of the use of the battery in the vehicle. The calculation section is configured to calculate the amount of damage to a housing of the battery by the internal pressure over the period in accordance with a result of the estimation by the estimation section after the end of the use of the battery in the vehicle. The prediction section is configured to predict the length of the durable period of the battery at the time of reuse in accordance with usage condition information and the amount of damage. The usage condition information indicates a usage condition of the battery imposed when the battery is reused after the end of the use.

According to the configuration, the amount of damage to the housing is calculated in accordance with the transition of the internal pressure of the housing from the start of the use of the battery. The length of the durable period of the battery at the time of reuse is then predicted in accordance with the usage condition of the battery at the time of reuse and the amount of damage. The length of the durable period of the battery at the time of reuse is hereby predicted accurately depending on the usage condition and the degree of damage to the housing by the internal pressure. It is thus possible to appropriately diagnose the reusability of the battery in accordance with a result of the prediction of the durable period.

The usage condition information may include the predictive values of the maximum SOC and the maximum temperature of the battery at the time of reuse. The storage unit may further store a plurality of first relationships defined in advance. The first relationships may each indicate a relationship between the predictive values of the maximum SOC and the maximum temperature and the length of the durable period for each of the amounts of damage. The prediction section may select a relationship corresponding to the amount of damage from the first relationships, and use the selected relationship to predict the length of the durable period in accordance with the predictive values of the maximum SOC and the maximum temperature.

The diagnosis system may further include a command output section. The command output section may be configured to, in a case where the length of the durable period predicted by the prediction section is less than the target length of the durable period, output a command of an instruction to take a predetermined measure to relieve the internal pressure.

The amount of increase in the amount of damage is smaller as the internal pressure is lower. According to the configuration, in a case where the predicted length of the durable period is less than the target length of the durable period, a user is prompted to take the predetermined measure. The internal pressure in the housing is hereby relieved and the increase rate of the amount of damage is therefore reduced. As a result, it is possible to elongate the time before the amount of damage reaches a limit value thereof. Thus, even in a case where the length of the durable period predicted by the prediction section is less than the target length, it is possible to make the length of the durable period greater than or equal to the target length to recover the residual value of the battery and allow the battery to be reused.

The predetermined measure may include a measure to store the battery over a predetermined relief period under at least one of a first condition, a second condition, and a third condition. The length of the relief period may be determined as the length of a period in which the internal pressure is relieved to make the length of the durable period greater than or equal to the target length. The first condition may be a condition that the temperature around the battery is lower than reference temperature. The second condition may be a condition that the pressure around the battery is lower than or equal to the internal pressure after the use of the battery in the vehicle comes to an end. The third condition may be a condition that the space around the battery is filled with gas different from the gas in the housing.

The estimation section may estimate the amount of increase in the internal pressure from the start of the use to the end of the use in accordance with a result of the estimation of the transition. The storage unit may further store a second relationship indicating the relationship between the amount of damage and the amount of increase, and the length of the relief period. The relationship is defined in advance. The diagnosis system may further include a determination section configured to use the second relationship to determine the length of the relief period in accordance with the amount of increase and the amount of damage.

According to the present disclosure, it is possible to appropriately diagnose the reusability of the battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating an overall configuration of a diagnosis system according to an embodiment;

FIG. 2 is a block diagram illustrating data stored in a storage device and a functional component of a control device;

FIG. 3 is a diagram exemplifying a data structure of a map;

FIG. 4 is a diagram exemplifying a map group and the data structure of the map;

FIG. 5 is a diagram for describing examples of transitions of internal pressure and an amount of damage in the embodiment and a comparative example thereof; and

FIG. 6 is a flowchart exemplifying a procedure of processing executed by a terminal apparatus in the embodiment.

### DETAILED DESCRIPTION OF EMBODIMENTS

Hereinafter, an embodiment of the present disclosure will be described in detail with reference to the drawings. The same or corresponding portions in the drawings will be denoted by the same reference numerals and will not be repeatedly described. The embodiment and respective modification examples thereof may be combined with each other as appropriate.

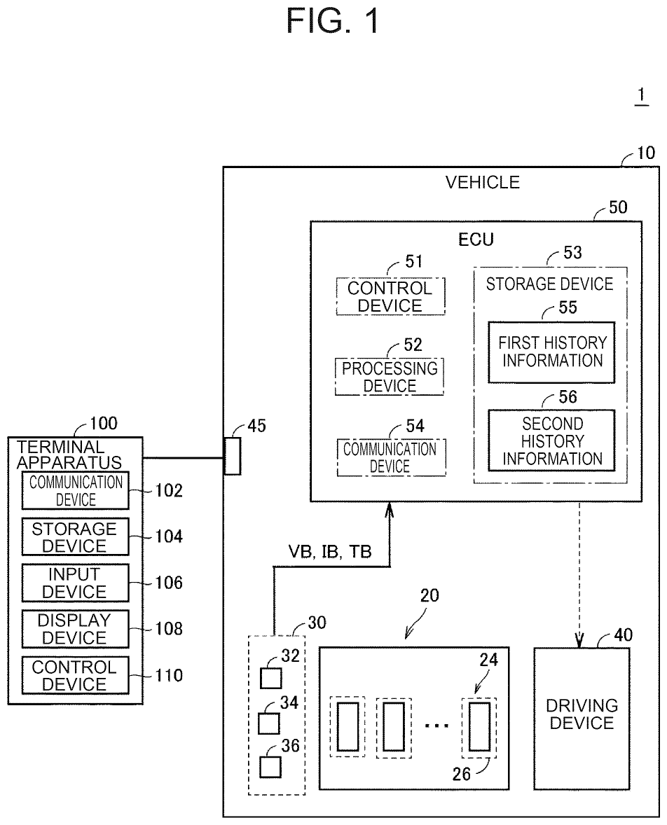

FIG. 1 is a diagram illustrating the overall configuration of a diagnosis system according to an embodiment. When FIG. 1 is referred to, a diagnosis system 1 includes a vehicle 10 and a terminal apparatus 100.

The vehicle 10 is an electrified vehicle, such as a battery electric vehicle (BEV), and includes an electric power storage device 20, a sensor group 30, a driving device 40, a connector 45, and an electronic control unit (ECU) 50.

The electric power storage device 20 includes a plurality of batteries 24. Each of the batteries 24 is a cell that stores electric power for the vehicle 10 to travel. The battery 24 includes a battery case 26, an electrode body including a positive electrode and a negative electrode, and an electrolyte solution. The battery case 26 is a housing that houses the electrode body. Each of the batteries 24 generates gas, such as carbon dioxide, in the battery 24 because of a chemical reaction caused when the battery 24 is charged with or discharges electricity. Each of the batteries 24 generates more gas as the electrode body thereof deteriorates more. The generation speed of the gas depends on the temperature or the like of each of the batteries 24. The generation of the gas may be a factor of increase in the internal pressure of the battery 24.

The battery case 26 includes a gas exhaust valve and a sealing member (none of them are illustrated). The gas exhaust valve may be opened in a case where the internal pressure of the battery 24 increases excessively. The sealing member may transmit the gas to the outside of the battery case 26. The transmission of the gas may be a factor of decrease in the internal pressure of the battery 24. The amount of transmitted gas depends, for example, on the temperature of the battery 24.

The sensor group 30 includes a voltage sensor 32, an electric current sensor 34, and a temperature sensor 36. The respective sensors detect a voltage VB, an electric current IB, and temperature TB of the battery 24. The driving device 40 includes an inverter and a motor (none of them are illustrated) and generates traction driving force for the vehicle 10 by consuming electric power of each of the batteries 24. An external apparatus of the vehicle 10 is connectable to the connector 45.

The ECU 50 includes a control device 51, a processing device 52, a storage device 53, and a communication device 54. The control device 51 controls the driving device 40 to control the charging and discharging of the battery 24.

The processing device 52 includes a memory and a processor (none of them are illustrated). The memory includes a read only memory (ROM) and a random access memory (RAM). The processor is, for example, a central processing unit (CPU) and executes various kinds of arithmetic processing in accordance with programs stored in the ROM. The processing device 52 sequentially calculates the states of charge (SOC) of the batteries 24, for example, based on the voltages VB, the electric currents IB, and the temperatures TB.

The storage device 53 stores first history information 55 and second history information 56. The first history information 55 indicates various process history items of the battery 24 and includes void volume information, inspection result information, and elapsed-time information. The void volume information indicates the volume of the void in the battery case 26. The volume of the void is defined by subtracting the total volume of the electrode body and the electrolyte solution of each of the batteries 24 from the volume of the battery case 26. The inspection result information indicates a result of an airtightness inspection carried out for the battery 24. The elapsed-time information indicates the elapsed time from the start of the use (the delivery of the vehicle 10 to a user) of each of the batteries 24 in the vehicle 10. The elapsed time is defined, for example, in units of months or years.

The second history information 56 includes histories of the voltage VB, the electric current IB, the temperature TB, and the SOC in a period (also referred to as a “vehicle installation period” below) in which each of the batteries 24 is installed in the vehicle 10. The history of the temperature TB includes temperature frequency indicating frequency (time) with which the temperature TB has each temperature value. The history of the SOC includes SOC frequency indicating frequency (time) with which the SOC has each value. The communication device 54 is capable of transmitting the first history information 55 and the second history information 56 to an external server.

The terminal apparatus 100 is a maintenance terminal at a dealer or the like and includes a communication device 102, a storage device 104, an input device 106, a display device 108, and a control device 110.

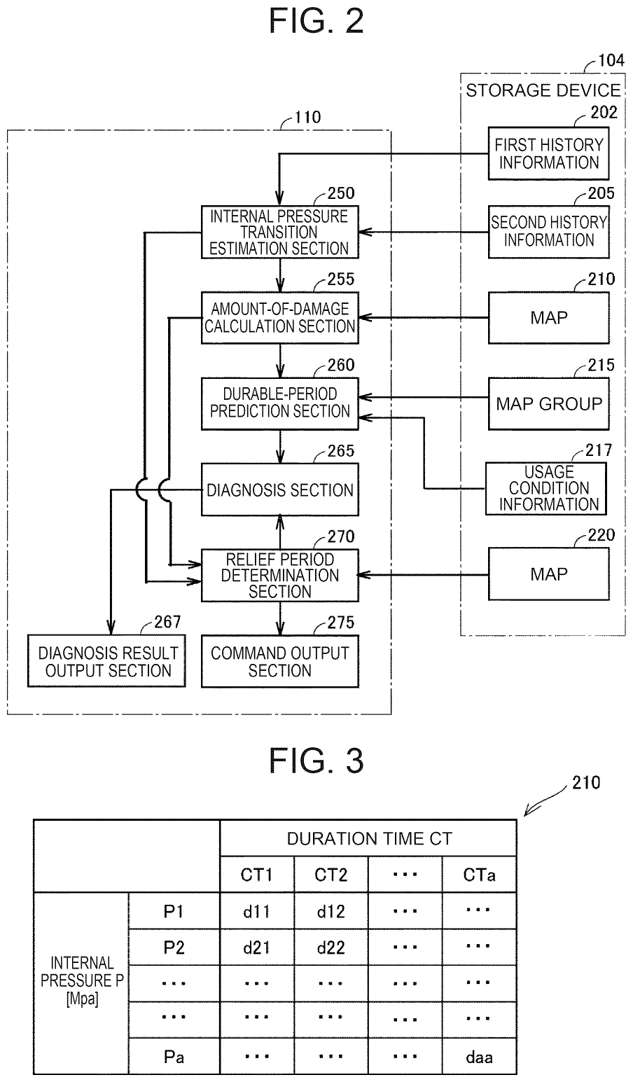

The communication device 102 obtains the first history information 55 and the second history information 56 from the storage device 53 of the vehicle 10 through a communication cable connected to the connector 45. In a case where the pieces of information are stored in the external server, the communication device 102 may obtain the pieces of information from the server through wired or wireless communication. The storage device 104 corresponds to an example of a “storage unit” according to the present disclosure and respectively stores the obtained first history information 55 and second history information 56 as first history information 202 and second history information 205 (FIG. 2) described below.

The input device 106 receives various user operations. The display device 108 displays various screens. The control device 110 controls the display device 108. The control device 110 includes a memory and a processor (none of them are illustrated). The memory includes a ROM and a RAM. The processor is, for example, a CPU and executes various kinds of arithmetic processing in accordance with programs stored in the ROM. As a result, the control device 110 functions as a processing device that executes various kinds of processing.

After used in the vehicle 10, the batteries 24 may be taken out from the vehicle 10 at a dealer or the like. Thereafter, in a case where the batteries 24 are each reusable, the battery 24 may be reused for desired application. It is thus important to appropriately diagnose the reusability of the battery 24.

In the vehicle installation period, the battery case 26 is easily damaged by the increasing internal pressure of the battery 24 caused by gas generated in the battery 24. The damage increases over time. The internal pressure changes depending on the elapsed time from the start of the use of the battery 24 in the vehicle 10 and basically increases in the long term. When the battery case 26 is damaged more by the internal pressure, the battery case 26 may be damaged by fatigue and the battery case 26 may be broken. As a result, it may be difficult to reuse the battery 24.

Accordingly, the terminal apparatus 100 of the diagnosis system 1 according to the present embodiment includes components that appropriately diagnose the reusability of the battery 24 and allow the battery 24 to be reused. The following gives description with regard to the points.

FIG. 2 is a block diagram illustrating data stored in the storage device 104 and functional components of the control device 110. When FIG. 2 is referred to, the storage device 104 stores the first history information 202, the second history information 205, maps 210, 220, a map group 215, and usage condition information 217.

The first history information 202 and the second history information 205 are the same as the first history information 55 and the second history information 56 stored in the storage device 53 of the ECU 50. The maps 210, 220, the map group 215, and the usage condition information 217 will be described below.

The control device 110 includes an internal pressure transition estimation section 250, an amount-of-damage calculation section 255, a durable-period prediction section 260, a diagnosis section 265, a diagnosis result output section 267, a relief period determination section 270, and a command output section 275 as functional components thereof. The functions are achieved when the processor of the control device 110 executes programs stored in the ROM.

The internal pressure transition estimation section 250 estimates the transition of the internal pressure of the battery 24 as follows in accordance with the first history information 202 and the second history information 205.

The internal pressure transition estimation section 250 estimates the value of the gas generation speed of the battery 24 at each timing in the vehicle installation period, for example, in accordance with the SOC and the temperature TB indicated by the second history information 205. The internal pressure transition estimation section 250 estimates the speed of increase in the internal pressure of the battery 24 at each timing in accordance with the estimated value of the gas generation speed and the void volume information of the first history information 202. The internal pressure transition estimation section 250 hereby estimates the amount of increase in the internal pressure at each timing in accordance with the speed of increase in the internal pressure and the elapsed time at each timing. The amount of increase is estimated, for example, by multiplying the speed of increase in the internal pressure by the square root of the elapsed time. The internal pressure transition estimation section 250 estimates the transition of the internal pressure of the battery 24 in the vehicle installation period in accordance with a predetermined initial reference value of the internal pressure and the amount of increase in the internal pressure. It is possible for the internal pressure transition estimation section 250 to estimate the total amount of increase in the internal pressure (also referred to as a “total internal pressure increase amount” below) over the vehicle installation period in accordance with a result of the estimation. The total internal pressure increase amount corresponds to the amount of increase in internal pressure P from the start of the use of each of the batteries 24 in the vehicle 10 to the end of the use of the battery 24.

The internal pressure transition estimation section 250 may estimate the amount of gas transmitted by the battery case 26 based on a history of the temperature TB and hereby estimate the speed of decrease in the internal pressure. In the case, the internal pressure transition estimation section 250 estimates the amount of decrease in the internal pressure in accordance with the speed of decrease in the internal pressure and the elapsed time. The amount of decrease is estimated, for example, by multiplying the speed of decrease in the internal pressure by the elapsed time. The internal pressure transition estimation section 250 may then calculate the difference between the amount of increase and the amount of decrease in the internal pressure estimated as described above and hereby estimate the total internal pressure increase amount.

The internal pressure transition estimation section 250 may correct the result of the estimation of the transition of the internal pressure in accordance with the inspection result information in the first history information 202. Alternatively, the internal pressure transition estimation section 250 may estimate the transition of the amount of gas transmitted by the sealing member described above in accordance with a history of the temperature TB and correct the result of the estimation of the transition of the internal pressure in accordance with a result of the estimation.

After the end of the use of each of the batteries 24 in the vehicle 10, the amount-of-damage calculation section 255 calculates the amount of damage to the battery case 26 (also referred to simply as the “amount of damage” below) by the internal pressure of the battery 24 over the vehicle installation period. As described below, the amount-of-damage calculation section 255 uses the map 210 to calculate the amount of damage in accordance with a result of the estimation of the internal pressure transition estimation section 250.

FIG. 3 is a diagram exemplifying the data structure of the map 210. When FIG. 3 is referred to, the map 210 indicates the relationship between the internal pressure P of the battery 24 and duration time CT of the internal pressure P, and the amount of increase in the amount of damage over the duration time CT. For example, in a case where a situation in which the internal pressure P is P1 continues for the time of CT1, the amount-of-damage calculation section 255 calculates the amount of increase in the amount of damage as d11. Thereafter, in a case where a situation in which the internal pressure P is P2 (>P1) continues for the time of CT2, the amount-of-damage calculation section 255 calculates the amount of increase in the amount of damage as d22. The amount-of-damage calculation section 255 integrates the amounts of increase thus calculated and hereby calculates the amount of damage over the vehicle installation period. The initial value of the amount of damage is, for example, zero. The map 210 is defined as appropriate in advance in an evaluation test or the like carried out beforehand. It is to be noted that the amount of increase (increase rate) in the amount of damage per unit time is smaller as the internal pressure P is lower. In other words, the battery case 26 is damaged less easily by the internal pressure P as the internal pressure P is lower.

When FIG. 2 is referred to again, the durable-period prediction section 260 predicts the length of the durable period of the battery 24 at the time of reuse in accordance with the amount of damage calculated as described above and the usage condition information 217. The period will also be referred to as a “reuse durable period”. The usage condition information 217 indicates a usage condition of each of the batteries 24 imposed when the battery 24 is reused after the end of the use of the battery 24 in the vehicle 10. The usage condition information 217 is defined as appropriate in advance by a user operation made with the input device 106. The usage condition information 217 includes, for example, the predictive values of the maximum SOC and the maximum temperature of the battery 24 at the time of reuse, which is not, however, limitative. The predictive values may be replaced with the setting values or the permissible values of the maximum SOC and the maximum temperature. As described below, the amount-of-damage calculation section 255 uses the map group 215 to predict the length of the reuse durable period.

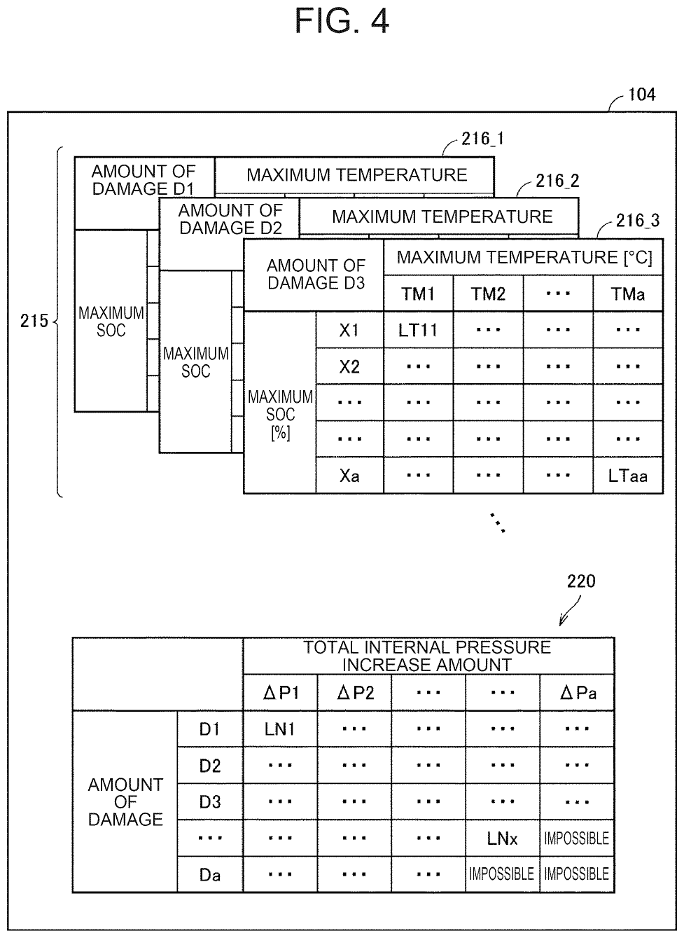

FIG. 4 is a diagram exemplifying the map group 215 and the data structure of the map 220. When FIG. 4 is referred to, the map group 215 includes maps 216_1, 216_2, 216_3 . . . . The maps each indicate the relationship between the predictive values of the maximum SOC and the maximum temperature of the battery 24 at the time of reuse and the length of the reuse durable period for each of the amounts of damage. The predictive values of the maximum SOC and the maximum temperature are defined as appropriate in advance based on the application of the battery 24 at the time of reuse.

For example, in a case where the amount of damage is calculated as D3, the durable-period prediction section 260 selects the map 2163 from the map group 215. The durable-period prediction section 260 then uses the map 2163 to predict the length of the reuse durable period in accordance with the predictive values of the maximum SOC and the maximum temperature of the battery 24 at the time of reuse. In one example, in a case where the respective predictive values of the maximum SOC and the maximum temperature are X1 and TM1, the durable-period prediction section 260 uses the map 2163 to predict the length of the reuse durable period as LT11.

The durable-period prediction section 260 predicts the length of the reuse durable period depending on a usage condition of the battery 24 at the time of reuse and the degree of damage to the battery case 26 by the internal pressure P. It is thus possible to accurately predict the length of the reuse durable period.

When FIG. 2 is referred to again, the diagnosis section 265 switches the processing in accordance with whether or not the length of the reuse durable period predicted by the durable-period prediction section 260 is greater than or equal to the target length of the reuse durable period. The target length is defined as appropriate in advance based on the application of the battery 24 at the time of reuse. In a case where the predicted length of the reuse durable period is greater than or equal to the target length, the diagnosis section 265 diagnoses the battery 24 as being reusable. In contrast, in a case where the predicted length of the reuse durable period is less than the target length, the diagnosis section 265 diagnoses the battery 24 as being difficult to reuse. As described above, the diagnosis section 265 makes it possible to appropriately diagnose the reusability of the battery 24 in accordance with a result of the prediction of the reuse durable period.

In a case where the battery 24 is diagnosed as being reusable, the diagnosis result output section 267 generates a command for the display device 108 to output (display) a result of the diagnosis. The result of the diagnosis is hereby displayed on the display device 108 and a user is notified thereof. As a result, the battery 24 is reused for desired application. For example, the reused battery 24 is incorporated into a reuse product and the product is sold.

In contrast, in a case where the battery 24 is diagnosed as being difficult to reuse, the length of the reuse durable period is insufficient and it is not thus necessarily possible to reuse the battery 24 as described above. However, even in such a case, a predetermined internal pressure relief measure is taken to allow the internal pressure P to be relieve and allow the reuse durable period to extend. The internal pressure relief measure is a measure taken to store the battery 24 over a predetermined period under a condition appropriate for relieving (reducing) the internal pressure P. Details of the condition will be described in detail below. The predetermined period will also be referred to as a “relief period”. An advantage of the internal pressure relief measure will be described below.

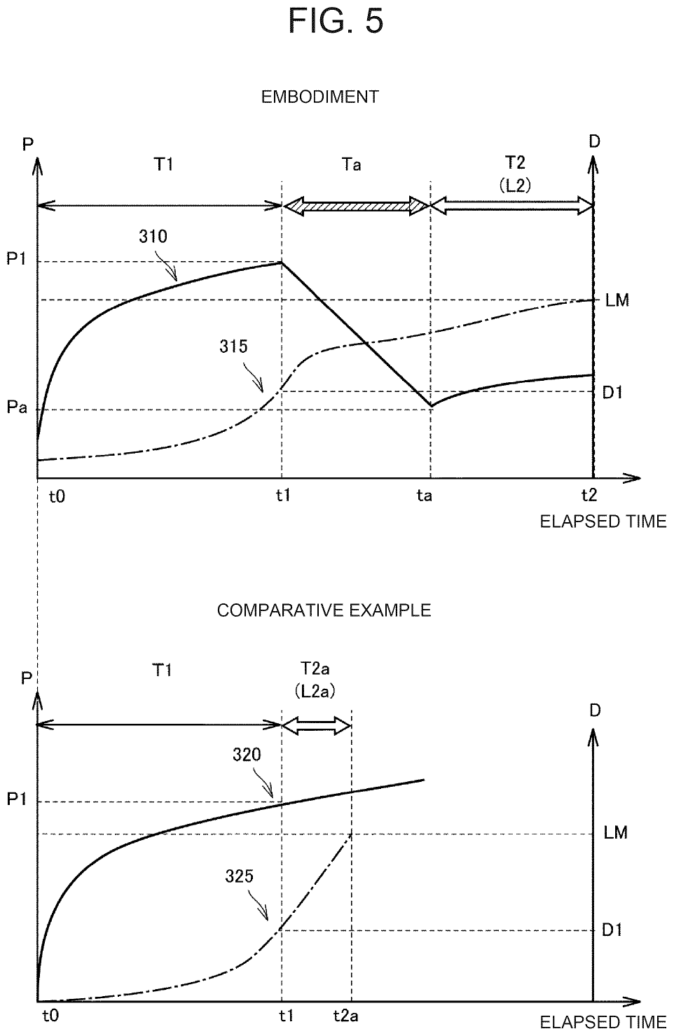

FIG. 5 is a diagram for describing examples of the transitions of the internal pressure P and the amount of damage in the embodiment and a comparative example thereof. The embodiment assumes that the battery 24 is reused after the battery 24 is taken out from the vehicle 10 and an internal pressure relief measure is taken. The comparative example assumes that the battery 24 is immediately reused with no internal pressure relief measure taken after the battery 24 is taken out from the vehicle 10.

When FIG. 5 is referred to, lines 310, 315 respectively represent the transitions of the internal pressure P and the amount of damage D in the embodiment. Lines 320, 325 respectively represent the transitions of the internal pressure P and the amount of damage D in the comparative example.

A period T1 corresponds to a vehicle installation period and is defined as the period from time t0 to time t1. At time t0, the use of each of the batteries 24 in the vehicle 10 is started. At time t1, the use of the battery 24 in the vehicle 10 comes to an end and the battery 24 is taken out from the vehicle 10. In the period T1, the embodiment and the comparative example have no differences in the internal pressure P and the amount of damage D. For example, in any of the embodiment and the comparative example, the internal pressure P is P1 and the amount of damage D is D1 at time t1.

In the comparative example, after the batteries 24 are each taken out from the vehicle 10, the battery 24 is immediately reused in a period T2a. The period T2a is the period from time t1 to time t2a. As described above, as the internal pressure P is higher, the amount of damage D has a higher increase rate. The internal pressure P (P1) at time t1 is relatively high (line 320). The amount of damage D therefore increases easily in the period T2a and reaches a limit amount of damage LM at time t2a (line 325). As a result, the length of the reuse durable period in the comparative example is merely L2a.

In contrast, in the embodiment, an internal pressure relief measure is taken in a period Ta. Thereafter, the batteries 24 are each reused in a period T2. The period Ta is the period from time t1 to time ta and corresponds to the relief period described above. The period T2 is the period from time ta to time t2. The internal pressure relief measure relieves the internal pressure P and lowers the internal pressure P from P1 to Pa. The internal pressure P (Pa) at time ta is relatively low (line 310) and the amount of damage D therefore has a low increase rate in the period T2 (line 315). In other words, during the reuse of the battery 24, the amount of damage D increases less easily than in the comparative example. As a result, the length of the reuse durable period is L2 (>L2a). It is assumed that L2 is greater than the target length of the reuse durable period.

As described above, it is possible in the embodiment to extend the length of the reuse durable period by the internal pressure relief measure and make the length of the reuse durable period greater than or equal to the target length. Thus, even in a case where the length of the reuse durable period predicted by the durable-period prediction section 260 is less than the target length, it is possible to recover the residual value of the battery 24 by the internal pressure relief measure and allow the battery 24 to be reused.

When FIG. 4 is referred to again, the map 220 indicates the relationship between the amount of damage D and the total internal pressure increase amount, and the length of the relief period. The length of the relief period in the map 220 is determined as the length of a period in which the internal pressure P is relieved to make the length of the reuse durable period greater than or equal to the target length. It is to be noted that “impossible” in FIG. 4 means that it is not possible for the length of the reuse durable period to reach the target length depending on some combinations of the amounts of damage D and the total internal pressure increase amounts in spite of an internal pressure relief measure. In other words, “impossible” indicates that it is not possible to determine the length of the relief period for a corresponding combination of the amount of damage D and the total internal pressure increase amount. The map 220 is defined as appropriate in advance in an experiment or the like.

When FIG. 2 is referred to again, the relief period determination section 270 uses the map 220 to determine the length of the relief period in accordance with the total internal pressure increase amount and the amount of damage D after the end of the use of the battery 24 in the vehicle 10. For example, in a case where the total internal pressure increase amount is ΔP1 and the amount of damage D is D1, the relief period determination section 270 determines the length of the relief period as LN1 (see FIG. 4). Additionally, in a case where the length of the durable period corresponding to the total internal pressure increase amount and the amount of damage D indicates “impossible” in the map 220, the relief period determination section 270 determines that it is not possible to determine the length of the relief period.

The map 220 may be defined for each of process history items indicated by the first history information 202 or for each of usage conditions indicated by the usage condition information 217. It is hereby possible to determine the length of the relief period more appropriately depending on a process history of the battery 24 or a usage condition of the battery 24 at the time of reuse.

In a case where the predicted length of the reuse durable period is less than the target length and it is possible to determine the length of the relief period, the command output section 275 outputs a command that instructs a user of the diagnosis system 1 to take an internal pressure relief measure. The user is, for example, a mechanic at a dealer. The command is output, for example, to cause the display device 108 to display a screen of an instruction to take an internal pressure relief measure. Such a screen is hereby displayed on the display device 108 and the user is therefore prompted to take an internal pressure relief measure. As a result, it is possible to make the length of the reuse durable period greater than or equal to the target length as described in FIG. 5. In a case where it is possible to determine the length of the relief period as described above, the diagnosis section 265 diagnoses the battery 24 as being reusable. In contrast, in a case where it is not possible to determine the length of the relief period, the diagnosis section 265 diagnoses the battery 24 as being difficult to reuse.

The internal pressure relief measure will be described in detail below. The internal pressure relief measure corresponds to a measure taken to store the battery 24 over the relief period under at least one of a first condition, a second condition, and a third condition described below. The first condition is a condition that the temperature around the battery 24 is lower than reference temperature. The reference temperature is, for example, zero degrees Celsius. The second condition is a condition that the pressure around the battery 24 is lower than or equal to the internal pressure P after the use of the battery 24 in the vehicle 10 comes to an end (i.e., after the vehicle installation period). The third condition is a condition that the space around the battery 24 is filled with gas (e.g., nitrogen gas) different from the gas in the battery case 26.

A gas-generating reaction and electrode deterioration of the battery 24 are restrained under the first condition. The speed of increase in the internal pressure P is hereby reduced. Additionally, the temperature is low under the first condition and the amount of damage D thus increases less easily even if the internal pressure P increases. Gas generated in each of the batteries 24 is transmitted more to the outside of the battery case 26 under the second condition. The internal pressure P hereby decreases more easily because of gas ventilation. It is possible to transmit the gas, such as carbon dioxide gas, in the battery case 26 to the outside because of the difference between the partial pressure of the gas in the battery case 26 and the pressure of the gas in the space therearound different from the gas in the battery case 26 under the third condition. As described above, the battery 24 is stored under at least one of the first to third conditions. The internal pressure P is hereby relieved and the amount of damage D is allowed to have a lower increase rate. It is hereby possible to appropriately extend the length of the reuse durable period and allow the battery 24 to be reused.

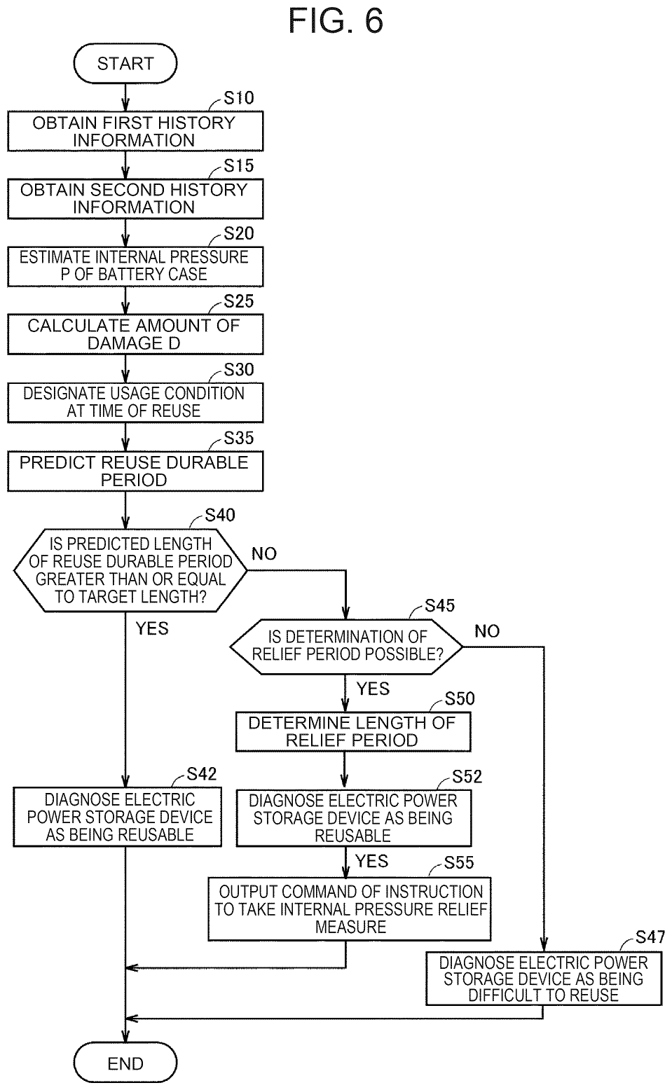

FIG. 6 is a flowchart exemplifying a procedure of processing executed by the terminal apparatus 100 in the embodiment. The flowchart starts when the terminal apparatus 100 is connected to the connector 45 through the communication cable. Before the flowchart starts, the batteries 24 may already be taken out from the vehicle 10 or the batteries 24 in the electric power storage device 20 may remain installed in the vehicle 10.

When FIG. 6 is referred to, the terminal apparatus 100 obtains the first history information 55 from the vehicle 10 and stores the first history information 55 in the storage device 104 as the first history information 202 (S10). The terminal apparatus 100 obtains the second history information 56 from the vehicle 10 and stores the second history information 56 in the storage device 104 as the second history information 205 (S15). The terminal apparatus 100 estimates the transition of the internal pressure P of each of the batteries 24 in the vehicle installation period in accordance with the first history information 202 and the second history information 205 (S20). The terminal apparatus 100 uses the map 210 to calculate the amount of damage D in accordance with a result of the estimation in S20 (S25). The terminal apparatus 100 receives the input of a user operation of designating the usage condition information 217 indicating a usage condition of the battery 24 at the time of reuse (S30). In the example, the usage condition information 217 includes the predictive values of the maximum SOC and the maximum temperature. The terminal apparatus 100 uses the map group 215 to predict the reuse durable period in accordance with the usage condition information 217 and the amount of damage D (S35).

The terminal apparatus 100 switches the processing in accordance with whether or not the predicted length of the reuse durable period is greater than or equal to the target length (S40). In a case where the predicted length of the reuse durable period is greater than or equal to the target length (YES in S40), the terminal apparatus 100 diagnoses the battery 24 as being reusable (S42). After S42, the terminal apparatus 100 displays, on the display device 108, a screen indicating a result of the diagnosis in S42 and brings the processing to an end. In a case where the predicted length of the reuse durable period is less than the target length (NO in S40), the terminal apparatus 100 uses the map 220 to switch the processing in accordance with whether or not it is possible to determine the length of the relief period (S45).

In a case where it is not possible to determine the length of the relief period (NO in S45), the terminal apparatus 100 diagnoses the battery 24 as being difficult to reuse (S47). After S47, the terminal apparatus 100 displays, on the display device 108, a screen indicating a result of the diagnosis in S47 and brings the processing to an end. In contrast, in a case where it is possible to determine the length of the relief period (YES in S45), the terminal apparatus 100 determines the length of the reuse durable period corresponding to the total internal pressure increase amount and the amount of damage D (S50). The terminal apparatus 100 then diagnoses the battery 24 as being reusable (S52). Subsequently, the terminal apparatus 100 outputs, to the display device 108, a command that instructs a user to take an internal pressure relief measure (S55), and displays, on the display device 108, a screen of the instruction to take the internal pressure relief measure.

As described above, according to the embodiment, the length of the reuse durable period is accurately predicted based on the amount of damage D by the internal pressure P. It is hereby possible to appropriately diagnose the reusability of the battery 24. Furthermore, in a case where the predicted length of the reuse durable period is less than the target length, a user is prompted to take an internal pressure relief measure. As a result, it is possible to appropriately extend the length of the reuse durable period and make the length of the reuse durable period greater than or equal to the target length. It is thus possible to recover the residual value of the battery 24 and allow the battery 24 to be reused.

### Other Modification Examples

The terminal apparatus 100 may calculate the internal pressure P and the amount of damage D in accordance with the first history information 55 and the second history information 56 in the storage device 53 of the ECU 50. In the case, the storage devices 53, 104 each correspond to an example of a “storage unit” according to the present disclosure.

The embodiment disclosed herein should be understood as an example in all respects, but should not be understood as being limitative. The scope of the present disclosure is demonstrated by the claims instead of the description. The scope of the present disclosure is intended to include the equivalents to the claims and all modifications within the scope of the claims.

What is claimed is:

1. A diagnosis system that diagnoses reusability of a battery, the diagnosis system comprising:
a storage unit configured to store history information indicating histories of a voltage, an electric current, and temperature of the battery in a period in which the battery is installed in a vehicle;
an estimation section configured to estimate transition of internal pressure of the battery in accordance with the history information, the internal pressure changing depending on elapsed time from a start of use of the battery in the vehicle;
a calculation section configured to calculate an amount of damage to a housing of the battery by the internal pressure over the period in accordance with a result of the estimation by the estimation section after an end of the use of the battery in the vehicle; and
a prediction section configured to predict a length of a durable period of the battery at a time of reuse in accordance with usage condition information and the amount of damage, the usage condition information indicating a usage condition of the battery imposed when the battery is reused after the end of the use.

2. The diagnosis system according to claim 1, wherein
the usage condition information includes predictive values of maximum SOC and maximum temperature of the battery at the time of reuse,
the storage unit further stores a plurality of first relationships defined in advance and the first relationships each indicate a relationship between the predictive values of the maximum SOC and the maximum temperature and the length of the durable period for each of the amounts of damage, and
the prediction section
selects a relationship corresponding to the amount of damage from the first relationships, and
uses the selected relationship to predict the length of the durable period in accordance with the predictive values of the maximum SOC and the maximum temperature.

3. The diagnosis system according to claim 1, further comprising a command output section configured to, in a case where the length of the durable period predicted by the prediction section is less than a target length of the durable period, output a command of an instruction to take a predetermined measure to relieve the internal pressure.

4. The diagnosis system according to claim 3, wherein
the predetermined measure includes a measure to store the battery over a predetermined relief period under at least one of a first condition, a second condition, and a third condition,
a length of the relief period is determined as a length of a period in which the internal pressure is relieved to make the length of the durable period greater than or equal to the target length,
the first condition is a condition that a temperature around the battery is lower than a reference temperature,
the second condition is a condition that a pressure around the battery is lower than or equal to the internal pressure after the use of the battery in the vehicle comes to an end, and
the third condition is a condition that a space around the battery is filled with a gas different from a gas in the housing.

5. The diagnosis system according to claim 4, wherein
the estimation section estimates an amount of increase in the internal pressure from the start of the use to the end of the use in accordance with a result of the estimation of the transition,
the storage unit further stores a second relationship indicating a relationship between the amount of damage and the amount of increase, and the length of the relief period, the relationship being defined in advance, and
the diagnosis system further comprises a determination section configured to use the second relationship to determine the length of the relief period in accordance with the amount of increase and the amount of damage.
